(19) United States
(12) Patent Application Publication
(10) Pub. No.: US 2021/0259085 A1
(43) Pub. Date: Aug. 19, 2021

(54) ELECTRIC PULSE MONITOR FOR AN ELECTRIFIED ELEMENT

(71) Applicant: TransGard LLC, York, PA (US)

(72) Inventors: Ryan Escure, York, PA (US); William Reichard, York, PA (US)

(21) Appl. No.: 17/150,486

(22) Filed: Jan. 15, 2021

Related U.S. Application Data
(60) Provisional application No. 62/976,643, filed on Feb. 14, 2020.

(51) Int. Cl. H05C 1/04; H03K 5/125; H03K 5/19

(52) U.S. Cl. CPC H05C 1/04; H03K 5/19; H03K 5/125

(57) ABSTRACT

A monitor for an electrical control system has a pulse detection circuit configured to detect a voltage waveform output to an electrified element. The monitor also has a monitor processor. The monitor processor receives the voltage waveform from the pulse detection circuit, measures one or more parameters of the voltage waveform, receives additional information associated with the voltage waveform, compares the one or more parameters to the additional information, and performs an analysis process based on the comparison of the voltage waveform and the additional information. The monitor also has a communication interface configured to deliver a result of the analysis process to an interface component via one or more communication components connected to the monitor processor.

### CROSS REFERENCE TO RELATED APPLICATIONS

This application claims the benefit of priority of U.S. Provisional Patent Application Ser. No. 62/976,643, filed on Feb. 14, 2020, the entire contents of which are hereby incorporated by reference herein.

### TECHNICAL FIELD

The present disclosure relates to electrified elements such as electric fences, and, more particularly, to an electric pulse monitor for an electrified element.

### BACKGROUND

Perimeter fencing, such as electrified fences, are used to keep trespassers from entering protected areas. Generally, a basic electricity energizer is used to deliver a voltage to conductive portions of the fence. Such energizers apply high voltage at quick cycles, such as 10,000V pulses every 1.5 seconds. However, these systems are not able to determine an actual voltage waveform that is being delivered to the electric fence or determine the data surrounding any problems. Indeed, at least some current systems have no feedback system at all that would enable a user to understand or be alerted to the functioning of an electric fence system and the associated voltage being applied. The disclosed system and methods address these and other problems of the prior art.

### SUMMARY

In one aspect, the present disclosure includes embodiments of a monitor for an electrical control system. The monitor includes a pulse detection circuit configured to detect a voltage waveform output to an electrified element. The monitor also includes a monitor processor. The monitor processor receives the voltage waveform from the pulse detection circuit, measures one or more parameters of the voltage waveform, receives additional information associated with the voltage waveform, compares the one or more parameters to the additional information, and performs an analysis process based on the comparison of the voltage waveform and the additional information. The monitor also includes a communication interface configured to deliver a result of the analysis process to an interface component via one or more communication components connected to the monitor processor.

### BRIEF DESCRIPTION OF THE DRAWINGS

FIG. 1 is a schematic view of an electrical system including an electrified element and an electrical control system, according to disclosed embodiments;

FIG. 2 is a block diagram of an exemplary electrical control system, consistent with disclosed embodiments;

FIG. 3 is a flowchart of an exemplary process for generating a voltage pulse for being applied to an electrified element, according to disclosed embodiments; and

FIG. 4 is a flowchart of an exemplary process for monitoring a voltage pulse waveform, according to disclosed embodiments.

### DETAILED DESCRIPTION

Perimeter fencing such as electrified fencing is helpful in keeping wildlife from entering and damaging outdoor structures such as power plants or electrical sub-stations. This invention is a monitoring system apparatus that is primarily used for electric pulse systems. Such systems could be electric fence energizers. This monitoring system apparatus is a standalone device that can be used with other systems via a physical interface or protocol. The monitoring system apparatus can measure electric pulse waveforms, capture and store the waveforms for future analysis, and save waveforms for reference. The monitoring systems intelligence can analyze incoming waveforms for specific operations criteria and identify the separate operational states. The individual waveforms can be categorized and stored. If the elements of the incoming waveform are abnormal the monitoring device can provide feedback to the electric pulse generator via a serial protocol. The abnormal waveform will be saved and flagged for analysis by a user. The user can be alerted by the monitoring device via alarm delivery and receive the abnormal waveform for export.

The interaction with external devices can be passive when such devices are asking for data feedback on the waveforms, or the monitoring device can be active, controlling the external devices as needed based off the waveform analysis. This monitoring device can also provide measurements on the attached conductor conditional elements for operational control.

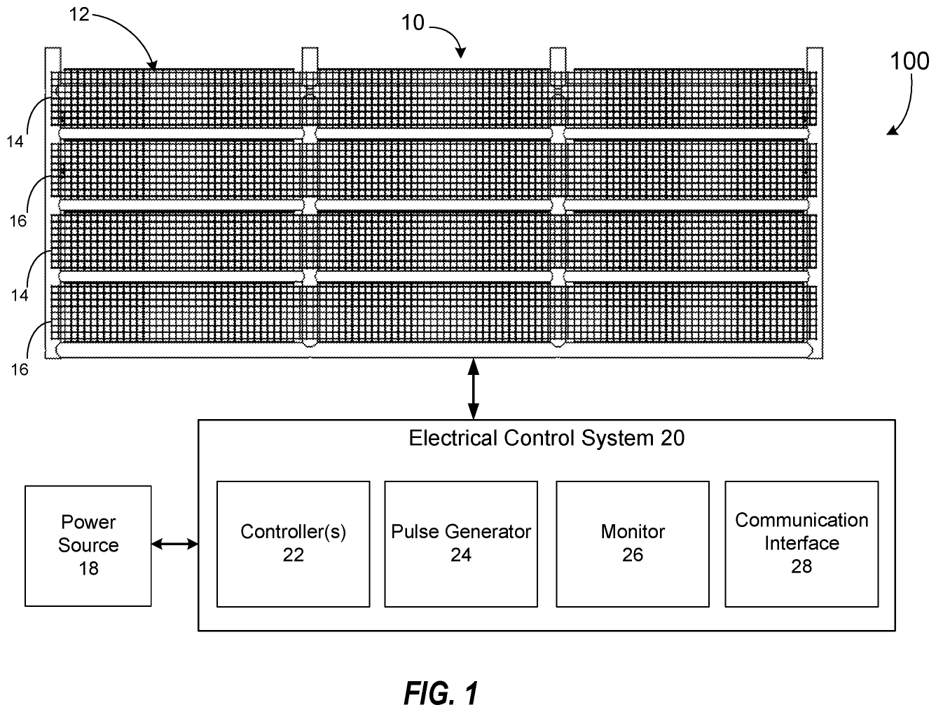

FIG. 1 is a schematic diagram of an exemplary electrical system 100. The electrical system 100 includes an electrified element 10 and an electrical control system 20. In an exemplary embodiment, the electrified element 10 is an electric fence having a panel portion 12 configured to receive an electrical pulse from the electrical control system 20. The panel portion 12 may include exposed conductive elements configured to divert the electrical pulse via contact with the panel portion 12 such that the electrified element 10 may be used as a deterrent barrier against entry to a particular area. In an exemplary embodiment, the panel portion 12 includes positive panels 14 and negative panels 16. The positive panels 14 and the negative panels 16 may be connected to the electrical control system 20 separately and not connect to each other in the field. A power source, such as a DC voltage source may be connected to the electrical control system 20 in order to deliver the electric pulse to the electrified element 10. While embodiments depict the electrified element 10 as a fence, it should be understood that other embodiments may include other elements for receiving an electrical pulse from the electrical control system 20, such as other types of physical barriers or other systems that require a controlled DC pulse generation.

The electrical control system 20 may be a computerized system configured to direct an electric pulse through the electrified element 10. In an exemplary embodiment, the electrical control system 20 includes at least one controller 22, a pulse generator 24, a monitor 26, and a communication interface 28. The at least one controller 22, in some embodiments, may include a control processor associated with the pulse generator 24 and a control processer associated with the monitor 26. In some embodiments, the at least one controller 22 may be a combined processor associated with functions of both the pulse generator 24 and the monitor 26. In an embodiment, the controller 22, the pulse generator 24, the monitor 26, and the communication interface 28 can be separate devices. In another embodiment, the controller 22, the pulse generator 24, the monitor 26, and the communication interface 28 can be integrated into a single device. In another embodiment, any of the controller 22, the pulse generator 24, the monitor 26, and the communication interface 28 can be integrated into one or more devices.

The at least one controller 22 is configured to provide instructions to the pulse generator 24 to deliver an electrical pulse to the electrified element 10. The monitor 26 may be configured to monitor the pulse generator 24 and receive feedback from the electrified element 10 to monitor the voltage and current (and associated parameters) being delivered to the electrified element 10 and provide information to the at least one controller 22 to further control the electrical control system 20. The at least one controller 22, pulse generator 24, and/or monitor 26 are configured to provide data to and/or receive data from the communication interface 28 in order to enable user control and communication of the electrical control system 20. The communication interface 28 may include communication components configured to facilitate the transfer of data to and from the electrical control system 20 (e.g., via wired and/or wireless connections).

In some embodiments, the communication interface 28 may include one or more sensors configured to detect a condition or setting. For instance, the communication interface 28 may include one or more time, date, location, temperature, humidity, on/off condition, current detection, etc. sensors. The communication interface 28 may be configured to provide a signal indicative of a parameter from one or more sensors to the pulse generator 24 and/or the monitor 26 for use in one or more disclosed processes.

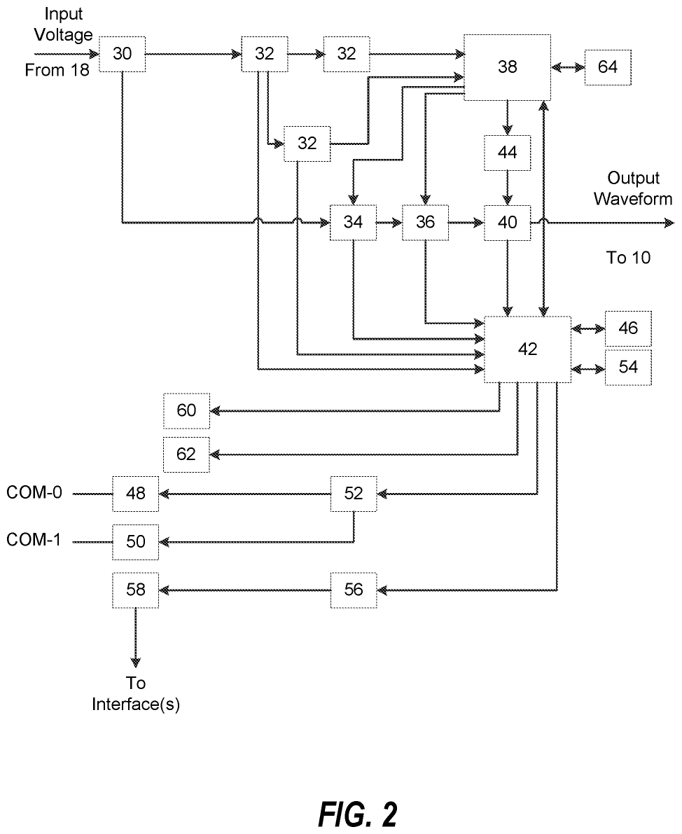

FIG. 2 is a block diagram of an exemplary embodiment of the electrical control system 20. In an exemplary embodiment, the electrical control system 20 is configured to receive 12 volts DC at power input terminals 30. In some embodiments, the power input terminals 30 may connect to power supply elements 32 (e.g., DC to DC transformers, voltage dividers, etc.) for powering controller elements (e.g., controllers, amplifiers, transformers, output devices, beacons, etc.) of the electrical control system 20. For instance, the power supply elements 32 may provide specific and separate voltages to the controller elements (e.g., low power in the range of 3-5 V).

The electrical control system 20 may further include the pulse generator 24 in the form of, for example, a charge circuit 34, a fire control circuit 36, and an energizer processor 38. The energizer processor 38 may be one of the one or more controllers 22. The charge circuit 34 includes, for example, power regulation components, charge capacitors, and primary transformers. For instance, the charge circuit 34 may control the input voltage to a primary charge transformer, and feed primary output voltage to the fire control circuit 36. The fire control circuit 36 may receive commands from the energizer processor 38 to control pulse generation. For example, such commands may include but are not limited to pulse amplitude, pulse duration, and pulse frequency, by releasing its input voltage to an output transformer 40. The output transformer 40, which may be a high voltage output transformer, boosts the pulsed output voltage to desired values and delivers an output waveform to the electrified element 10.

In an exemplary embodiment, the monitor 26 is connected to elements of the pulse generator 24 for monitoring the functioning of the electrical control system 20. In some embodiments, the monitor 26 includes a monitor processor 42. In an exemplary embodiment, the energizer processor 38 receives pulse generation confirmation from the charge and fire control circuits 36 to verify that a pulse has been generated, and uses this fault condition to flag the monitor processor 42 that a fault condition exists. The monitor processor 42 and the energizer processor 38 communicate with each other for advanced operational control and feedback. In an embodiment, the monitor processor 42 and the energizer processor 38 can be separate processors, and the two processors can communicate with each other. In another embodiment, the monitor processor 42 and the energizer processor 38 can be integrated into a single device. In other words, a single processor can fulfill the functions of both the monitor processor 42 and the energizer processor 38.

The monitor processor 42 monitors at least the output transformer 40 for waveform analysis providing feedback to the energizer processor 38 for controlling the pulse generation process. In an exemplary embodiment, the monitor processor 42 collects and stores captured waveform data, voltage, and current readings into a flash memory, for alarm notification actions, or use by external systems data collection operations, and/or is pushed to a cloud-based server for storage and analysis. The monitor processor 42 may implement software algorithms to perform pattern recognition, waveform analysis, fault condition determination, adjustment of feedback settings in the energizer processor 38, component health, fence conditions (loss of bonding, shorts, resistance, and current, etc.).

The monitor 26 may further include a pulse detection circuit 44 connected to the output transformer 40. The pulse detection circuit 44 and monitor processor 42 may communicate to perform direct waveform measurements, and collected data may be analyzed via algorithms to detect waveform matching with programmed control output by the energizer processor 38 and its associated charge circuit 34. The monitor processor may calculate adjustment offsets and communicate such adjustments to the energizer processor 38 for adjustment to the pulse output control algorithm. The monitor processor 42 may also continuously analyze raw waveform data for pattern recognition to determine multiple fault and system operating parameters (shorts, bonding loss, organism shorting conditions, potential offsets, fence continuity, fence current, etc.). Information derived from the raw waveforms is also monitored for alarm threshold event detection. The monitor processor 42 may provide an alert based on a threshold event detection, such as through local reports, beacon states, relay states, protocol messages, SMS text messages, email notifications, communication with an external cloud-based server, etc., for secondary processing (e.g., via the communication interface 28). The monitor processor 42 may also periodically push collected and stored data to an external server and web portal where they are presented in raw, scaled, and other formats for reporting, charting, and advanced data analysis (e.g., via the communication interface 28).

The communication interface 28 may be connected to at least the monitor processor 42 for enabling delivery and receipt of data in relation to the functioning of the electrical control system 20. The communication interface 28 may include one or more communications ports for high level communications, such as USB connection 46 for high-level programming and setup, a COM-0 connection 48 for programming and remote client/server interface, a COM-1 connection 50 for remote client/server interface. The monitor processor 42 may connect to the COM-0 and COM-1 connections 48, 50 as RS232 serial ports through, for example, a serial hardware transceiver 52 used for local touchscreen human machine interface. A JTAG port 54 may also be provided in connection with the monitor processor 42 for low-level programming. A transceiver 56 (e.g., an IEEE-RS485 transceiver) is provided for connection to a user interface 58, such as an external communication device used for poling system register data.

In some embodiments, one or more mechanical relays 60, 62 are provided for local annunciation states, or for interface to external systems for the purpose of fault condition reporting. According to some embodiments, an expansion connector 64 is provided for the installation of peripheral expansion boards, for additional functionality. The electrical control system 20, according to some embodiments, also incorporates a data-logger device included in the energizer processor 38 and a remote communication interface for secondary data collection and processing, and for external connection to supervisory systems, such as systems connected by cellular, satellite, Ethernet, Wi-Fi, Bluetooth®, or other port connections (e.g., RS232, RS485 ports).

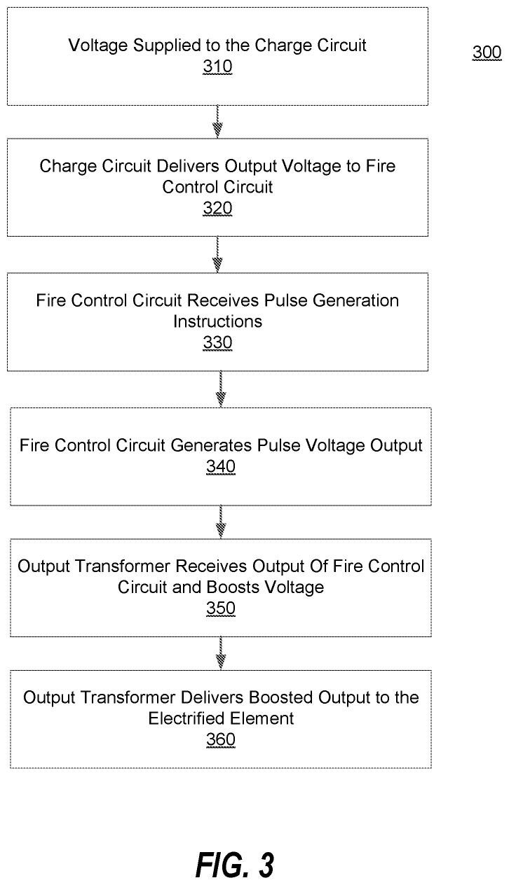

FIG. 3 is an example of an exemplary process 300 for generating an electrical pulse to be delivered to an electrified element 10, such as an electric fence panel 12. The controller(s) 22 and additional components of the pulse generator 24 may operate in conjunction with each other in order to convert an input DC voltage into an output voltage waveform to be applied to the electrified element 10.

In step 310, DC voltage is supplied to the charge circuit 34. For instance, 12 volts DC may be supplied from the power source 18 to the charge circuit 34 having one or more capacitors and one or more transformers for storing and delivering electricity. In step 320, the charge circuit 34 may deliver an output voltage to the fire control circuit 36. The fire control circuit 36 is configured to output a voltage.

In step 330, the fire control circuit 36 receives pulse generation instructions from the energizer processor 38. In step 340, the fire control circuit 36 generates a pulsed voltage output according to pulse generation instructions from the energizer processor 38. The pulsed voltage output includes parameters including pulse amplitude, pulse duration, pulse pause duration, pulse amperage, and pulse frequency.

In step 350, the output transformer 40 receives the pulsed output from the fire control circuit 36 and boosts the output voltage to a desired value. For instance, the output transformer 40 may perform a passive voltage transformation based on a rating of the transformer. In step 360, the output transformer applies the boosted output waveform to the electrified element 10, such as the electric fence panel 12.

According to process 300, the energizer processor 38 is configured to determine a customized voltage pulse waveform to be applied to the electrified element 10. For instance, the energizer processor 38 may determine an appropriate setting for the waveform and provide instructions to the fire control circuit 36 for the parameters of an output waveform. The energizer processor 38 may determine the appropriate setting based on various factors and/or inputs entered by a user for initial calculations. Once the initial parameters have been set, the energizer processor 38 may adjust the output waveform based on environmental elements and/or electrical or mechanical inputs that would affect the waveform on the electrified element 10.

In one example, the energizer processor 38 may receive input from another component of the electrical control system 20 for determining the parameters of a waveform. For instance, the energizer processor 38 may receive an alert from the communication interface 28 indicating one or more settings, such as a selected use, a location, a time of day, a temperature, etc. The settings may be user input, such as a selection made via the user interface 58. The settings may be automatically determined from one or more sensors, such as location, time, temperature, etc. The energizer processor 38 may determine one or more parameters based on the received setting.

In another example, the energizer processor 38 may determine instructions based on communication with the monitor 26 (e.g., monitor processor 42). For instance, the energizer processor 38 may receive an alert that the output waveform is outside of one or more guidelines (e.g., UL69 guidelines) and attempt to correct the issue through instructions to the fire control circuit 36. If the device is unable to correct the output, the energizer processor may issue an instruction to disable the pulse and notify a user through the communication interface 28. In some embodiments, the energizer processor 38 may compare feedback from the monitor 26 with instructions to assess the health of the energizer processor 38 or the pulse generator 24 in general.

The energizer processor 38 is configured to provide alerts to one or more users through the communication interface 28. For instance, one or more LED lights may be operated via local HMI and beacons (e.g., a red light for operational, yellow light for fault condition). In another example, relays 60 and 62 could be used as outputs to an external SCADA system or monitoring circuit. In some embodiments, one or more of the devices 48, 50, 58 may deliver data to an input/output device (e.g., a touchscreen) to provide feedback to a user. In another example, the expansion connector 64 may deliver data to a server for logging data and use of the system over a period of time.

The disclosed embodiments include the monitor 26 in communication with the pulse generator 24 such that the waveform and associated data are captured by the monitor 26 for analysis and monitoring. For instance, the pulse detection circuit 44 may be connected to one or more of the energizer processor 38, the output transformer 40, the fire control circuit 36, and/or the monitor processor 42 for determining one or more of the instructions for a voltage output waveform (e.g., from the energizer processor 38) and an actual output waveform (e.g., from the output transformer 40) and deliver such information to the monitor processor 42. In some embodiments, the monitor processor 42 may communicate directly with the energizer processor 38 to determine the instructions for a waveform output. In still other embodiments, the monitor processor 42 and the energizer processor 38 may be combined as one processor.

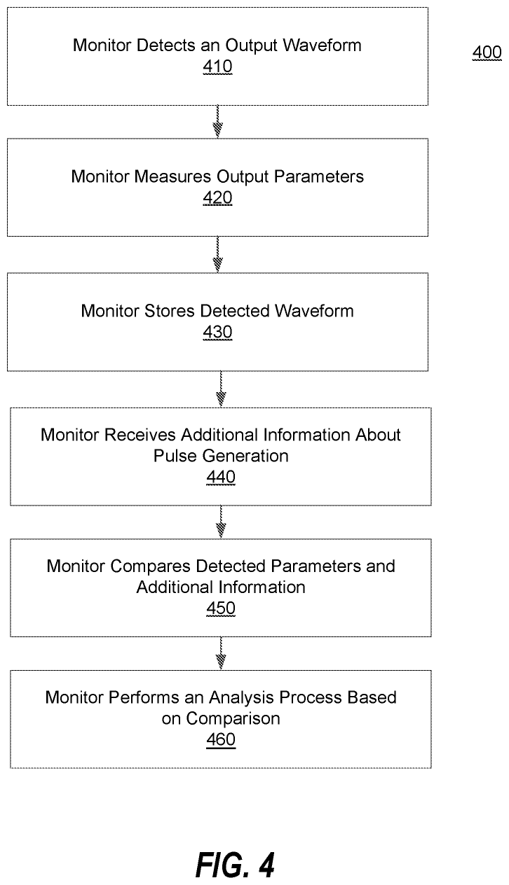

FIG. 4 is a flowchart of an exemplary process 400 for monitoring the electrical control system 20. The monitor 26, such as the monitor controller 42 (as one of the one or more controllers 22) may perform one or more steps of the process 400. The controller(s) 22 and additional components of the monitor 26 may operate in conjunction with each other in order to monitor both the input for generating a customized voltage waveform and an actual voltage output applied to the electrified element 10.

In step 410, the monitor 26 detects an output waveform. For instance, the pulse detection circuit 44 may detect that the output transformer 40 is receiving, boosting, and delivering an output voltage and providing data to the monitor processor 42. In step 420, the monitor 26 measures one or more parameters of the output waveform. For example, the monitor 26 may measure pulse amplitude, pulse duration, pulse pause duration, pulse amperage, and pulse frequency of the output waveform. It should be understood that different components may detect and measure the output waveform.

In step 430, the monitor 26 stores the detected waveform to internal memory. For example, the monitor processor 42 may capture and store the detected waveform, such as by delivering the captured waveform and measured parameters to a server or other component through the communication interface 28. The monitor 26 may deliver the detected waveform for logging of activity of the pulse generator 24 over time.

In some embodiments, steps 420 and 430 may be combined and/or reversed and/or repeated. For instance, the monitor processor 42 may deliver raw data to another component (e.g., via the communication interface 28) for measurement of the various parameters associated with the detected waveform.

In step 440, the monitor 26 receives additional information about pulse generation. For example, the monitor processor 42 may communicate with the energizer processor 38 to receive information about the instructions for a voltage pulse that were delivered by the energizer processor 38 to the fire control circuit 36. In another example, the monitor processor 42 may receive information about acceptable waveform parameters. For instance, the monitor processor 42 may receive acceptable guideline parameters (e.g., UL69 guidelines), acceptable parameters for a particular setting, known waveform categories, short or open criteria, etc.

In some embodiments, the monitor 26 may categorize the detected waveform (e.g., based on one or more parameters and/or patterns over time). For example, the monitor processor 42 may compare the waveform, its parameters, and/or a pattern of various waveform patterns to known categories of waveforms and determine whether the detected waveform matches one or more known categories. In some embodiments, the categories may be associated with operational states of the electrical control system 20.

In step 450, the monitor 26 may compare the detected and measured waveform to the additional information. For instance, the monitor processor 42 may compare the detected waveform parameters with the instruction parameters provided by the energizer processor 38 to determine whether the pulse generator 24 is operating correctly. In another embodiment, the monitor 26 may compare the waveform to acceptable parameters, such as UL69 guidelines to determine whether the system is operating outside of acceptable parameters. In other embodiments, the monitor 26 may compare the waveform category to known categories to determine whether the system is operating in a manner that is known and/or acceptable. In some instances, the monitor 26 may compare the measured parameters to data regarding a short or open criteria to determine whether such an event has occurred.

In step 460, the monitor 26 is configured to perform an analysis process based on the comparison and determine a result of the analysis process. For instance, the monitor 26 may compare a detected voltage waveform to additional information to determine a fault condition, such as an abnormal waveform or other output from the pulse generator 24. The monitor processor 42 may work in conjunction with one or more of the communication interface 28 components to deliver an alert to a user (e.g., sound an alarm, trigger a communication relay, push an SMS message, email, etc., or otherwise provide communication to a user via an interface). In some embodiments, the analysis process may include flagging an abnormal waveform such that it can be reviewed after it is communicated to a user interface.

The elements of the figures are not exclusive. Other embodiments may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention.

What is claimed is:

1. A monitor for an electrical control system, comprising:
a pulse detection circuit configured to detect a voltage waveform output to an electrified element;
a monitor processor configured to:
receive the voltage waveform from the pulse detection circuit,
measure one or more parameters of the voltage waveform;
receive additional information associated with the voltage waveform;
compare the one or more parameters to the additional information; and
perform an analysis process based on the comparison of the voltage waveform and the additional information; and
a communication interface configured to deliver a result of the analysis process to an interface component via one or more communication components connected to the monitor processor.

2. The monitor of claim 1, wherein the one or more parameters of the voltage waveform comprise one or more of a pulse amplitude, pulse duration, pulse pause duration, pulse amperage, and pulse frequency.

3. The monitor of claim 1, wherein the additional information comprises parameter instructions for a pulse generator to generate the voltage waveform.

4. The monitor of claim 3, wherein the analysis process includes determining whether the measured one or more parameters differ from the parameter instructions.

5. The monitor of claim 4, wherein the result of the analysis process is a health of a pulse generator.

6. The monitor of claim 1, wherein the additional information comprises one or more guideline parameters for operation.

7. The monitor of claim 6, wherein the result of the analysis process is an alert that a pulse generator is operating outside of the guideline parameters.

8. The monitor of claim 1, wherein the additional information includes one or more categories for waveforms.

9. The monitor of claim 8, wherein the categories of waveforms correspond to operational states of a pulse generator.

10. The monitor of claim 8, wherein the analysis process is a categorization of the voltage waveform based on the received one or more categories.

11. The monitor of claim 10, wherein the result of the analysis process is a finding that the voltage waveform does not fit into the one or more categories.

12. The monitor of claim 1, wherein the result of the analysis process is one or more instructions for generating a voltage waveform and the monitor processor is configured to deliver the one or more instructions to a pulse generator.

13. The monitor of claim 1, wherein the electrified element is an electric fence panel.
